(19) United States
(12) Patent Application Publication
(10) Pub. No.: US 2003/0001218 A1
(43) Pub. Date: Jan. 2, 2003

(54) Semiconductor device with high driving force and less impurity punch-through and method of manufacturing the same

(76) Inventor: Mariko Takagi, Kawasaki-shi (JP)

Correspondence Address: PILLSBURY WINTHROP, LLP, P.O. BOX 10500, MCLEAN, VA, 22102, US

(21) Appl. No.: 10/231,237

(22) Filed: Aug. 30, 2002

Related U.S. Application Data
(62) Division of application No. 09/404,538, filed on Sep. 24, 1999.

(30) Foreign Application Priority Data
Sep. 24, 1998 (JP) 10-270102
Sep. 21, 1999 (JP) 11-267332

(51) Int. Cl. H01L 29/76

(52) U.S. Cl. 257/410

(57) ABSTRACT

A gate insulating film is formed of an oxynitride film prepared by adding nitrogen atoms to a thermal oxide film. The Si—N bonds each having a second adjacent oxygen atom as viewed on the basis of the nitrogen atom within the oxynitride film are positioned at least one atomic layer inside the interface between the silicon substrate and the oxynitride film to allow the gate insulating film to prevent boron atoms contained in the gate electrode from being migrated through the gate insulating film without lowering the driving force of the transistor.

### BACKGROUND OF THE INVENTION

The present invention relates to a semiconductor device and a method of manufacturing the same, particularly, to a CMOS field effect transistor device and a method of manufacturing the same.

In recent years, problems such as generation of a short channel effect are generated in accordance with miniaturization of transistors and, thus, a dual gate CMOS structure is employed for suppressing the short channel effect. In the dual gate CMOS structure, an N⁺-type polycrystalline silicon (polysilicon) gate electrode having, for example, arsenic (As) introduced therein is formed in the N-channel transistor, and a P⁺-type polysilicon gate electrode having, for example, boron (B) introduced therein is formed in the P-channel transistor. In the case of employing the dual gate CMOS structure, however, boron in the polysilicon gate electrode of the P-channel transistor is diffused into the underlying silicon (Si) substrate in the subsequent heat treating step, particularly, in the heat treating step for activating the impurities in the source and drain regions, leading to serious problems. For example, the transistor characteristics are deteriorated or changed. Also, the reliability of the gate insulating film is lowered.

For overcoming the above problems, it is known to the art to use as the gate insulating film an oxynitride film prepared by adding nitrogen (N) to the gate insulating film. However, if the added nitrogen atoms are present in an excessively large amount at the interface between the oxynitride film and the silicon substrate, the driving force of the transistor is markedly deteriorated.

The particular problem will now be described with reference to FIG. 10. Specifically, FIG. 10 is a graph in which transistor T1 (not shown) including a gate insulating film having a thickness of 4 nm, to which nitrogen was added by using a N₂O gas, is compared with transistor T2 (not shown) including a gate insulating film consisting of a thermal oxide film having a thickness of 4 nm in respect of the driving force and the boron punch-through through the gate insulating film. These transistors T1 and T2 were prepared by exactly the same method except the method of forming the gate insulating film.

FIG. 10 covers the case where a rapid temperature elevation annealing (RTA) was performed at 1020° C. for 20 seconds after introduction of boron into the polysilicon gate of the P-channel transistor. The planar density of the added nitrogen is plotted on the abscissa of the graph. The driving force ratio based on the use of the thermal oxide film (T2) is plotted on the ordinate on the right side of the graph. Further, the flat band shifting amount caused by the boron punch-through from the P⁺-polysilicon layer and the n-well capacitor is plotted on the ordinate on the left side of the graph.

FIG. 10 clearly shows that, where the planar density of the added nitrogen is not less than 2.2×10¹⁴/cm², the driving force ratio (Idsat/Idsat0) of transistor T1 (Idsat) to transistor T2 (Idsat0) is not higher than 95% of the thermal oxide film.

On the other hand, where the planar density of the added nitrogen is not higher than 1.5×10¹⁴/cm², the flat band shifting amount caused by the boron punch-through is not smaller than 0.1V, giving rise to a problem in controlling the threshold value. Also, under the planar density noted above, the flat band shifting amount is greatly dependent on the added nitrogen amount. As a result, the transistor characteristics are greatly affected by the nonuniformity in the added nitrogen concentration.

Under the circumstances, where the gate insulating film is 4 nm thick and the RTA is performed at 1020° C. for 20 seconds, it is reasonable to state that an optimum concentration of the added nitrogen, at which both the driving force deterioration and the boron punch-through can be controlled, falls within a range of between 1.5×10¹⁴/cm² and 2.2×10¹⁴/cm².

As described above, in order to provide a CMOS transistor exhibiting good transistor characteristics, it is necessarily required to use an oxynitride film having an optimum nitrogen dose amount.

The graph of FIG. 10 shows the boron punch-through under the typical activation process at 1020° C. for 20 seconds. On the other hand, FIG. 11 is a graph showing the dependency of flat band shifting amount on added nitrogen atoms concentration, covering the case where the boron punch-through takes place under the lowermost condition at which the effect of the activation process can be expected, e.g., at 950° C. for 30 seconds. It should be noted that the flat band shifting amount is a good indicator for boron punch-through. A higher flat band shifting amount means that boron atoms are diffused in the Si substrate further.

FIG. 11 shows that nitrogen addition of about 5×10¹³/cm² is required even under the lowermost condition at which the effect of the activation can be expected.

It should also be noted that, where a trade off relationship can be observed between the driving force and the boron punch-through as shown in FIG. 10, the window for the optimum added nitrogen concentration is narrowed.

In the example of FIG. 10, the boron punch-through scarcely occurs where the added boron concentration is 3×10¹⁴/cm² or more. Therefore, a high concentration side can be used only in consideration of the boron punch-through. Incidentally, the boron punch-through is known to be dependent on the film thickness, the activating temperature and time. In the actual process, the film thickness and temperature are nonuniform on the wafer surface, nonuniform depending on the positions within the furnace, and nonuniform among lots (batches). Also, the added nitrogen concentration is somewhat nonuniform. Such being the situation, a margin relating to the boron punch-through is broadened if boron is added on a high concentration side. However, it is a practical serious problem that a sufficiently large process margin cannot be secured because the upper limit of the added nitrogen concentration is determined by the requirement of preventing the driving force of the transistor from being deteriorated. It is proposed in, for example, Japanese Patent Disclosure (Kokai) No. 7-335876 that the nitrogen concentration be lowered in the vicinity of the interface between the silicon substrate and the insulating film by re-oxidation of a N₂O oxynitride film so as to suppress deterioration of the driving current. In this case, however, the electron mobility in a region of high electric field, which determines the circuit operating speed, is rather deteriorated (FIG. 7, Sample C).

As described above, it was difficult in the past to prevent the boron punch-through without lowering the driving force of a transistor.

### BRIEF SUMMARY OF THE INVENTION

The present invention, which has been achieved for overcoming the above problems inherent in the prior art, is intended to provide a semiconductor device capable of preventing the impurities contained in the gate electrode from being migrated through the gate insulating film without lowering the driving force of a transistor and a method of manufacturing the same.

According to a first aspect of the present invention, there is provided a semiconductor device, comprising a semiconductor substrate, a gate insulating film formed on the semiconductor substrate, and a gate electrode formed on the gate insulating film, wherein the gate insulating film consists of an oxynitride film containing nitrogen atoms, the peak of Si—N bonds each having a second adjacent oxygen atom as viewed on the basis of the nitrogen atom in the oxynitride film being positioned apart from the interface between the semiconductor substrate and the oxynitride film by a distance of at least one atomic layer.

According to a second aspect of the present invention, there is provided a semiconductor device, comprising a semiconductor substrate, a gate insulating film formed on the semiconductor substrate, and a gate electrode formed on the gate insulating film, wherein the gate insulating film consists of an oxynitride film containing nitrogen atoms, the peak of nitrogen concentration in the oxynitride film being positioned apart from the interface between the semiconductor substrate and the oxynitride film by a distance of at least one atomic layer.

The planar density of the nitrogen atoms added to the gate insulating film should be at least about 5×10¹³/cm² and should not exceed about 3×10¹⁵/cm².

Also, the roughness of the interface between the oxynitride film and the semiconductor substrate should be equal to or smaller than the roughness of the interface between a thermal oxide film and the semiconductor substrate.

According to a third aspect of the present invention, there is provided a method of manufacturing a semiconductor device, comprising the steps of forming a gate insulating film on a semiconductor substrate, and forming a gate electrode on the gate insulating film, wherein the gate insulating film is formed by thermally oxidizing a surface region of the semiconductor substrate, followed by oxynitriding the thermal oxide film by substituting a NO gas within a furnace such that the oxygen content within the furnace is lowered to 1/10 or less of the mixed gas of NO and oxygen.

Further, according to a fourth aspect of the present invention, there is provided a method of manufacturing a semiconductor device, comprising the steps of forming a gate insulating film on a semiconductor substrate, and forming a gate electrode on the gate insulating film, wherein the gate insulating film is formed by oxynitriding a surface region of the semiconductor substrate by substituting a NO gas within a furnace such that the oxygen content within the furnace is lowered to 1/10 or less of the mixed gas of NO and oxygen.

The temperature for the oxynitriding treatment should be 700 to 1100° C.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIGS. 1A and 1B are cross sectional views collectively showing a process of manufacturing a semiconductor device of the present invention;

FIG. 2 shows a furnace control sequence in forming a gate insulating film in the present invention;

FIG. 3 is a graph showing the relationship between the vertically effective electric field and the electron mobility within an inversion layer with respect to various concentrations of added nitrogen atoms;

FIG. 4 is a graph showing the relationship between the positive stationary charge amount and the concentration of the added nitrogen atoms;

FIG. 5 is a graph showing the relationship between the positive stationary charge amount and the mobility component depending on the coulomb scattering;

FIG. 6 is a graph showing a nitrogen profile of a sample;

FIG. 7 is a graph showing the relationship between the vertically effective electric field and the electron mobility within an inversion layer with respect to another sample;

FIG. 8 is a graph showing the relationships between the mixed oxygen amount and the depth from the interface and between the mixed oxygen amount and the intensity ratio of Si—N bond/Si—O bond;

FIG. 9 is a graph showing the relationship between the oxynitriding temperature and the added nitrogen concentration;

FIG. 10 is a graph showing the relationships between the added nitrogen concentration and a flat band shifting amount and between the added nitrogen concentration and the driving force ratio in respect of a transistor including a gate insulating film formed by using a N₂O gas and another transistor including a gate insulating film consisting of a thermal oxide film; and

FIG. 11 is a graph showing the relationship between the added nitrogen concentration and the flat band shifting amount.

### DETAILED DESCRIPTION OF THE INVENTION

The outline of the present invention will now be described with reference to the accompanying drawings.

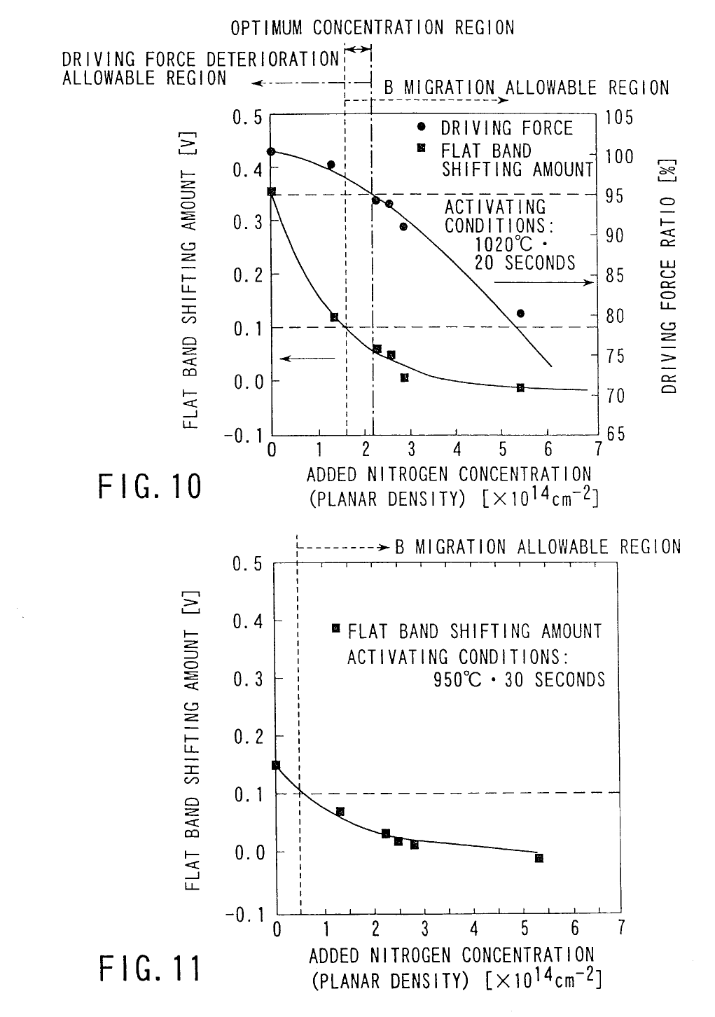

As apparent from FIG. 10, the driving force of a MOS transistor is lowered with increase in the added nitrogen concentration in a N₂O oxynitriding process. The low driving force is caused by the lowering in the mobility of the carriers (electrons and holes) within the inversion layer.

FIG. 3 shows the mobility of electrons (carriers) within an inversion layer in an oxynitride film formed by an N₂O oxynitriding process, relative to the vertical electric field with respect to various concentrations of the added nitrogen atoms. As shown in FIG. 3, the carrier mobility is prominently lowered regardless of the added nitrogen concentration in a region where the vertical electric field is relatively weak (0.7 MV/cm). In other words, the carrier is put in a state of low mobility with increase in the amount of the added nitrogen if the operating electric field region alone is taken into account. Therefore, it is reasonable to state that in the case of using an N₂O oxynitride film as a gate insulating film, the carrier mobility within an inversion layer is lowered with increase in the amount of the added nitrogen.

Causes of the mobility deterioration in the use of N₂O oxynitride film will be mentioned in detail, down below:

In general, the mobility (μ_{eff}) is defined by three mobility components consisting of mobility component (μ_{c}) owing to the coulomb scattering, mobility component (μₚₕ) owing to the phonon scattering, and mobility component (μₛᵣ) owing to the surface roughness scattering, as given below:

1/μ_{eff}=1/μ_{c}+1/μₚₕ+1/μₛᵣ

In FIG. 3, the ranges a, b, and c respectively indicate ranges where the mobility is determined in accordance with one of the coulomb scattering by electrons (range a), the phonon scattering (range b), and the surface roughness scattering (range c) as a dominant cause therein

The mobility of the hole is also considered to be determined by the mechanism similar to that of the electron. However, since an experimental confirmation of the dependency of each of the coulomb scattering, the phonon scattering and the surface roughness scattering on the vertical electric field, which was performed in respect of the electron mobility, has not yet been performed for the hole mobility, the discussion herein is made just with reference to the electron mobility. However, it is considered reasonable to understand that situations substantially similar to those for the electron mobility accompany the hole mobility.

Also, the mobility component (μₚₕ) owing to the phonon scattering (range b shown in FIG. 3), one of the above-mentioned three mobility components, is substantially constant regardless of the nitrogen addition amount to the gate insulation film. However, from FIG. 5 showing the relationship between the amount of the positive stationary charge and the mobility component owing to the coulomb scattering, it should be clearly understood that the mobility component (μ_{c}) owing to the coulomb scattering is lowered with increase in the amount of the stationary charge. Since the lowering of the mobility (μ_{eff}) is caused by the lowering of the mobility component (μ_{c}) owing to the coulomb scattering, it is important to suppress the lowering of the mobility component (μ_{c}) owing to the coulomb scattering in order to control deterioration of the mobility (μ_{eff}).

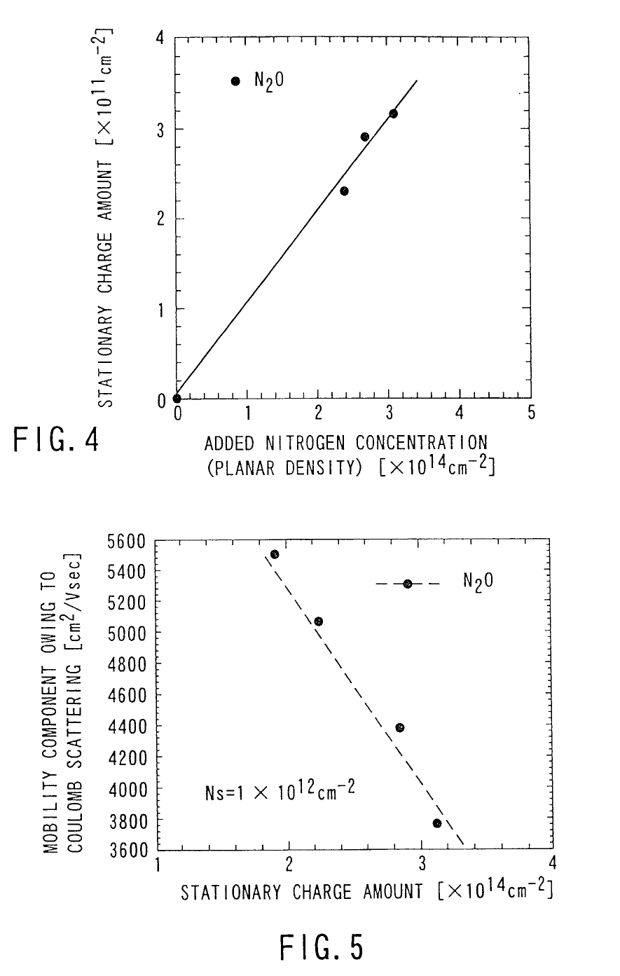

As shown in FIG. 4, the amount of the stationary charge is increased with increase in the amount of the added nitrogen. In other words, in the case where an oxynitride film is formed by using N₂O, the amount of the stationary charge is dependent on the amount of the added nitrogen. Therefore, the lowering of mobility is considered to be caused by the increase in the stationary charge/interfacial level brought about by the nitrogen addition.

The coulomb scattering denotes a mutual action between the coulomb potential formed by the charge forming the coulomb scattered body and a carrier in the inversion layer. However, the magnitude of the coulomb potential is exponentially decreased relative to the distance. Therefore, decrease of the mobility is considered to be suppressed, if the coulomb scattered body (stationary charge derived from bonds relating to Si—N in the case of an oxynitride film) is positioned away from the interface between the silicon substrate and the oxynitride film. In other words, it has been clarified that, in order to suppress the decrease of the mobility, it is important to control the position of the Si—N bond, in addition to the control of N dose amount.

In order to look into the relationship between the Si—N bond and the mobility, an experiment has been conducted by FT-IR (Fourier Transform Infrared Ray Spectroscopic analysis) using samples A and B to clarify the dependency between the ratio of the peak intensity of the Si—N bond to that of the Si—O bond (hereinafter, “Si—N/Si—O bond peak intensity ratio”) and the depth in the gate insulating film.

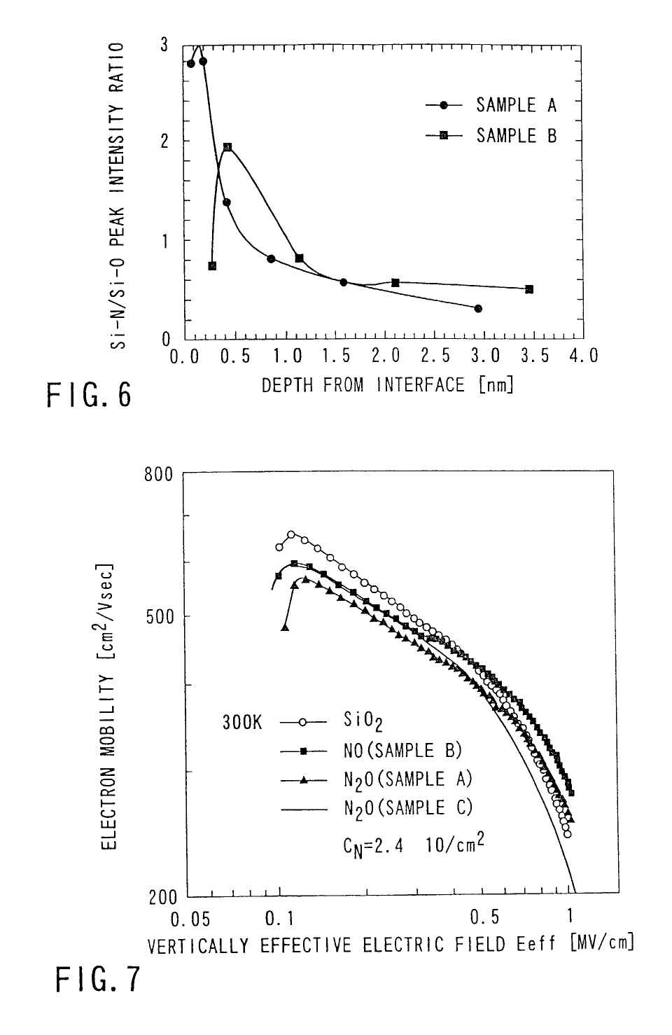

FIG. 6 is a graph showing a ratio of the peak intensity derived from the presence of the Si—N bond (more accurately, N—Si—O bond or Si—O—N bond) observed in the vicinity of 1000 cm⁻¹ to the peak intensity of the Si—O bond observed in the vicinity of 1100 cm⁻¹ (i.e., a signal observed in a thermal oxide film). The Si—N bond corresponds to a Si—N bond having a second adjacent oxygen (O) atom as viewed on the basis of the nitrogen atom (N). As seen from the graph, sample A has a profile such that the nitrogen concentration is increased toward the interface with the silicon substrate. On the other hand, sample B has a profile such that a peak of the nitrogen concentration is positioned about one atomic layer inside the interface with the silicon substrate. FIG. 7 is a graph showing the electron mobility for each of samples A and B having the particular profiles relative to the vertical electric field. As seen from the graph in FIG. 7, the deterioration in the mobility (μ_{eff}) relative to the vertically effective electric field in sample B is more suppressed, compared with that in sample A.

As described above, in order to suppress decrease of mobility, it is important not only to control the N dose amount, but also to add nitrogen to exhibit a profile such that the sites of the Si—N bonds are positioned about one atomic layer inside the interface to allow the peak of the nitrogen concentration to reside in the particular position. It is possible for the sites of the Si—N bonds to be positioned in an upper region of the gate insulating film as far as the Si—N bonds are positioned at least one atomic layer inside the interface with the silicon substrate.

It is important to suppress the oxidation reaction in introducing nitrogen in order to allow the Si—N bonds to be positioned inside the lowermost surface of the gate insulating film.

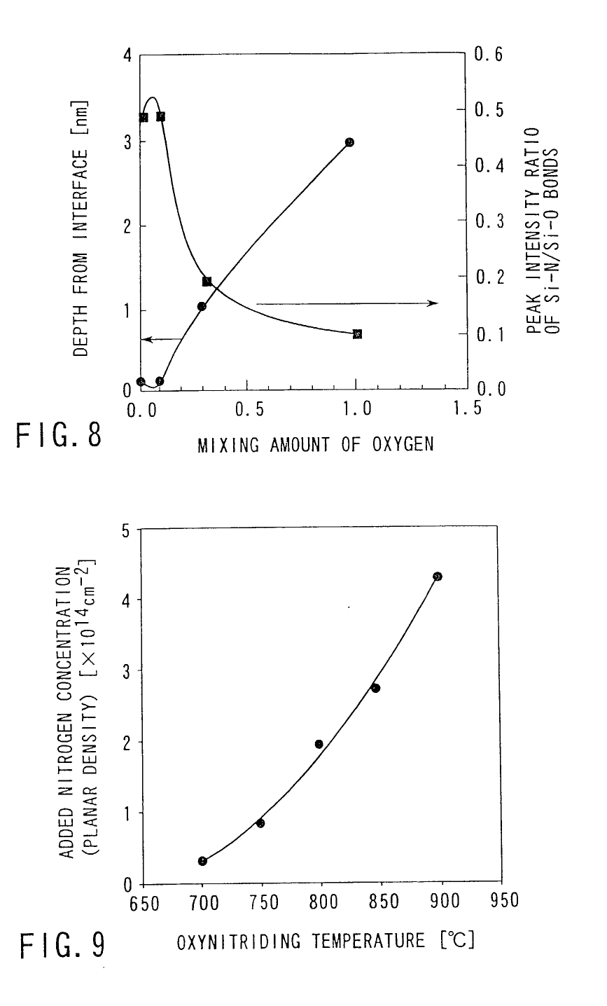

FIG. 8 is a graph showing the relationships between the oxygen amount contained in the gas introduced into the furnace in the oxynitriding step with NO and an intensity ratio (Y axis on the right side) of the Si—N bond to the Si—O bond at the interface with the silicon substrate and between the oxygen amount and the depth from the interface (Y axis on the left side) at which the peak intensity ratio of the Si—N bond to the Si—O bond (Si—N/Si—O bond peak intensity ratio) assumes the highest value. As apparent from the graph, the Si—N/Si—O bond peak intensity ratio is rapidly increased if the oxygen amount exceeds 1/10. Also, the position, i.e., the distance from the interface, at which the Si—N/Si—O bond peak intensity ratio is made maximum within the oxynitride film is substantially on the interface, if the oxygen amount is larger than 1/10. The reason for this is considered to be as follows.

Specifically, where the oxynitriding reaction and the oxidizing reaction proceed simultaneously, reconstruction is brought about by the oxidizing reaction at the interface between the silicon substrate and the silicon oxide film (SiO₂). As a result, a large number of Si—Si bonds or Si—O bonds whose coupling angles are distorted are formed at the interface. In this step, nitrogen is considered to enter the weak Si—Si coupling portion at the interface. On the other hand, where the oxidizing reaction does not proceed simultaneously with the oxynitriding reaction, Si—N coupling angle, etc. present in a region several angstroms inward of the lowermost interface is distorted. Further, nitrogen atoms enter the incomplete SiO₂ network, i.e., a so-called “sub-oxide region”. It follows that, in such a case, the highest nitrogen concentration is formed in a region slightly inward of the lowermost interface of the silicon substrate.

As described above, it is important to suppress generation and remanence of the oxidizing agent as much as possible in the nitrogen introducing step in order to prevent the oxidization of the gate insulating film simultaneous to the nitridation thereof, thereby to allow the Si—N bond to be positioned inside the lowermost surface of the gate insulating film. Particularly, it is important to suppress the oxygen amount introduced into the furnace to 1/10 or less, as apparent from FIG. 8.

(Embodiment)

One embodiment of the present invention will now be described with reference to the accompanying drawings.

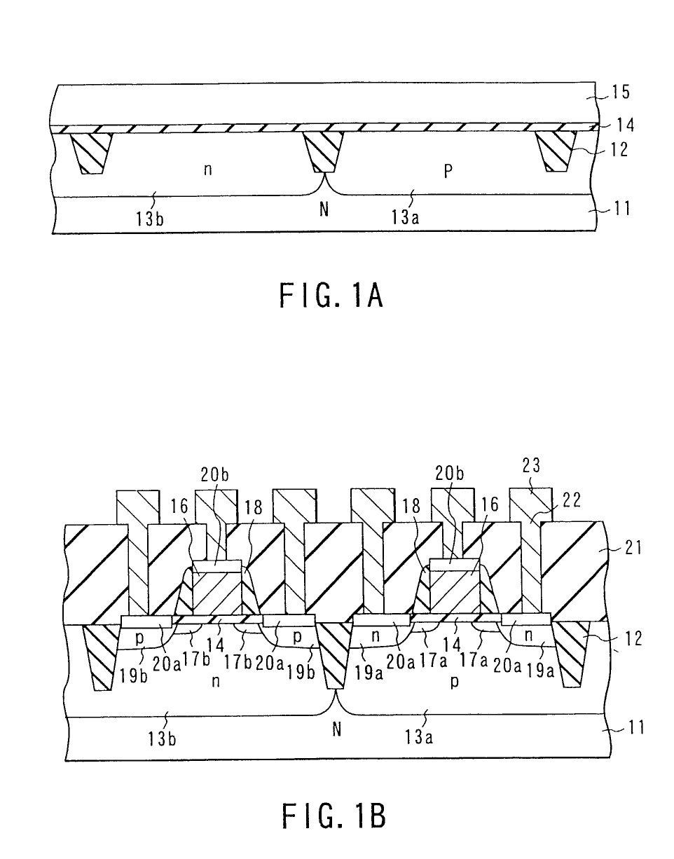

As shown in FIG. 1A, a plurality of element isolating oxide films 12 are formed within an N-type silicon substrate 11. The element isolating oxide film 12 shown in the drawing consists of an STI (shallow trench isolation). Alternatively, a LOCOS isolation can be employed for the element isolation. For example, a P-type impurity and an N-type impurity are introduced separately into the element regions within the silicon substrate 11 defined between the adjacent element isolating oxide films 12 so as to form a p-well 13a and an n-well 13b. Then, a gate insulating film 14 is formed on the surface of the silicon substrate 11, followed by depositing a polysilicon layer 15 in a thickness of, for example, 200 nm. How to form the gate insulating film 14 will be described hereinafter in detail.

Then, the polysilicon layer 15 is selectively removed by means of lithography and etching, followed by forming a plurality of gate electrodes 16 in some portions of the element regions, as shown in FIG. 1B. Further, an after-oxidation is performed for eliminating the damage done by the etching, followed by forming shallow source and drain regions 17a in the PMOSFET region by implanting, for example, boron ions under a lower accelerating energy and by forming shallow source and drain regions 17b in the NMOSFET region by implanting, for example, arsenic ions under a lower accelerating energy.

After formation of the source and drain regions, a silicon nitride (SiN) film is deposited on the entire surface, followed by selectively etching the silicon nitride layer by a reactive ion etching (RIE). As a result, side walls 18 are formed on both side surfaces of the gate electrode 16.

In the next step, a mask is formed in the PMOSFET region by a lithography method, followed by implanting an N-type impurity, e.g., arsenic ions, into the NMOSFET region by using the mask under a predetermined accelerating energy to form source and drain regions 19a having an impurity concentration lower than that in the source and drain regions 17a. Similarly, a mask is formed in the NMOSFET region by a lithography method, followed by implanting a P-type impurity, e.g., boron ions, into the PMOSFET region by using the mask under a predetermined accelerating energy to form source and drain regions 19b having an impurity concentration lower than that in the source and drain regions 17b.

Then, titanium (Ti) is deposited on the entire surface, followed by forming titanium silicide layers 20a and 20b on the source and drain regions 19a, 19b and on the gate electrodes 16 by the known salicide technology. Further, a silicon oxide film is deposited in a thickness of, for example, about 900 nm by LPCVD (low pressure chemical vapor deposition) method, followed by flattening the silicon oxide film by, for example, CMP (chemical mechanical polishing) method, thereby forming an interlayer insulating film 21.

In the next step, contact holes 22 are formed in the interlayer insulating film 21 at positions corresponding to the source and drain regions 19a, 19b, and the gate electrodes 16, followed by depositing an Al—Si—Cu layer on the entire surface in a thickness of about 400 nm. The resultant Al—Si—Cu layer is processed by means of lithography and etching to form a wiring layer 23 connected to the titanium silicide layers 20a and 20b.

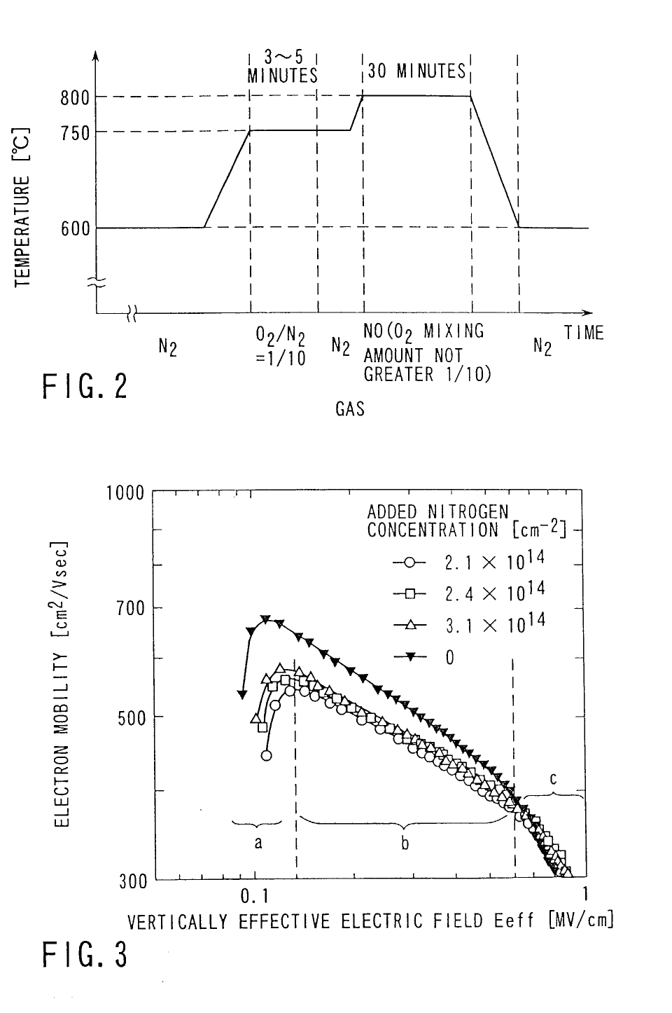

The gate insulating film 14 is formed as follows. Specifically, FIG. 2 schematically shows a series of process sequence of a furnace including the introduction of a wafer into the furnace, oxidation of the wafer with a diluted oxidizing agent, the oxynitriding and the delivery of the processed wafer out of the furnace.

Specifically, the nitrogen gas atmosphere within the furnace loaded with the wafer is maintained at, for example, 600° C. Under this condition, the entire wafer surface is oxidized for 3 to 5 minutes under an atmosphere of, for example, 750° C. using a gas prepared by diluting, for example, a dry O₂ with N₂ 10 times as much as the dry O₂ to form the thin gate insulating film 14 shown in FIG. 1A in a thickness of, for example, 1 to 2 nm. Then, the inner space of the furnace is consecutively purged with a nitrogen gas to substitute the nitrogen gas for the oxygen gas remaining within the furnace. The purging should be continued until the concentration of the oxygen gas remaining within the furnace is lowered to, for example, about 1 ppm or less.

Then, an oxynitriding treatment is carried out at about 800° C. for about 30 minutes under a NO atmosphere. In this step, it is important to control the oxynitriding atmosphere such that the oxygen amount within the furnace is 1/10 or less of the gas mixture within the furnace.

Where the gate insulating film 14 is formed as described above, the NO molecule forms a Si—NO bond or is separated into nitrogen and oxygen atoms to form a Si—N bond and a Si—O bond in the Si—O network in a sub-oxide region in the vicinity of the interface between the thin gate insulating film 14 and the silicon substrate 11. As a result, the nitrogen atoms are introduced into the oxide film. It should be noted that, by carefully controlling the gaseous atmosphere, the nitrogen atoms can be introduced into the gate insulating film 14 to exhibit a profile that the peak concentration of the nitrogen atoms is formed in a region slightly above the interface between the gate insulating film 14 and the silicon substrate 11. The planar density of the added nitrogen within the gate insulating film 14 should be at least, for example, 5×10¹³/cm². The upper limit of the added nitrogen concentration, in which Si₃N₄ is formed within the gate insulating film 14, is about 3×10¹⁵/cm², if Si₃N₄ layer forms a single atomic layer.

The roughness of the interface between the gate insulating film consisting of the oxynitride film formed by the process described above and the silicon substrate 11 should be equal to or lower than the roughness of the interface between a thermal oxide film and the silicon substrate. In this case, the carrier mobility across the interface within a region of a high electric field is rendered equal to or higher than that across the interface between the conventional thermal oxide film and the silicon substrate.

In the embodiment described above, the oxynitriding treatment is carried out at 800° C. within a furnace of atmospheric pressure. However, the oxynitriding temperature is not necessarily limited to 800° C.

The lower limit of the process temperature is determined by the efficiency of nitriding performed by diffusion/reaction of a NO gas. FIG. 9 is a graph showing the relationship between the oxynitriding temperature and the added nitrogen concentration (planar density), covering the case where the process time is set at 30 minutes. As apparent from the graph, nitrogen atoms scarcely enter the film under a process temperature of 700° C. or less. On the side of such a low temperature, the amount of nitrogen introduced into the film is not appreciably increased even if the process time is increased because the nitriding efficiency is determined by the reaction coefficient of the NO gas. It follows that the process under temperature of 700° C. or less is not practical.

On the other hand, the amount of the introduced nitrogen is increased with increase in the oxynitriding temperature. As described previously, it is generally undesirable to introduce a large amount of nitrogen into the film, because the driving force is deteriorated. However, a low nitrogen concentration can be achieved by performing the process of RTA in units of seconds on the high temperature process side. Under the circumstances, the upper limit of the process temperature is 1100° C. in view of the melting of the silicon substrate.

In the embodiment described above, the peak concentration of the Si—N bonds within the gate insulating film is positioned inward of the interface with the silicon substrate so as to suppress deterioration of the carrier mobility and to suppress deterioration of the driving force. As a result, the boron punch-through can be prevented.

It should also be noted that deterioration of the driving force dependent on the added nitrogen concentration is scarcely observed in the oxynitride film formed by the method of the present invention. As a matter of fact, the deterioration of the driving force was suppressed at 96% even where the planar concentration of the added nitrogen atoms was as high as 5×10¹⁴/cm². Therefore, the window of the optimum nitrogen addition amount was widened to fall within a range of between 1.5×10¹⁴/cm² and 5×10¹⁴/cm². Since the dependence of the driving force deterioration on the added nitrogen concentration is markedly diminished in the embodiment of the present invention, it is possible to use an oxynitride film having a high-added nitrogen concentration and to ensure a sufficiently large process margin.

In the embodiment described above, the gate insulating film is formed of an oxynitride film. Alternatively, another film such as a radical oxynitride film can be used as the gate insulating film. Further, the present invention can be worked in various modified fashions within the technical scope of the present invention.

As described above, the present invention provides a semiconductor device in which the impurity contained in the gate electrode is prevented from being migrated through the gate insulating film without lowering the driving force of the transistor and also provides a method of manufacturing the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device, comprising:
a semiconductor substrate;
a gate insulating film formed on the semiconductor substrate; and
a gate electrode formed on the gate insulating film;
wherein the gate insulating film comprises an oxynitride film containing nitrogen atoms, the peak of Si—N bonds each having a second adjacent oxygen atom as viewed on the basis of the nitrogen atom in the oxynitride film being positioned apart from the interface between the semiconductor substrate and the oxynitride film by a distance of at least one atomic layer.

2. A semiconductor device according to claim 1, wherein the planar density of the nitrogen atoms added to the gate insulating film is at least 5×10¹³/cm² and is not higher than about 3×10¹⁵/cm².

3. A semiconductor device according to claim 1, wherein the roughness of the interface between the oxynitride film and the semiconductor substrate is equal to or lower than the roughness of the interface between a thermal oxide film and the semiconductor substrate.

4. A semiconductor device, comprising:
a semiconductor substrate;
a gate insulating film formed on the semiconductor substrate; and
a gate electrode formed on the gate insulating film;
wherein the gate insulating film comprises an oxynitride film containing nitrogen atoms, the peak of the nitrogen concentration in the oxynitride film being positioned apart from the interface between the semiconductor substrate and the oxynitride film by a distance of at least one atomic layer.

5. A semiconductor device according to claim 4, wherein the planar density of the nitrogen atoms added to the gate insulating film is at least 5×10¹³/cm² and is not higher than about 3×10¹⁵/cm².

6. A semiconductor device according to claim 4, wherein the roughness of the interface between the oxynitride film and the semiconductor substrate is equal to or lower than the roughness of the interface between a thermal oxide film and the semiconductor substrate.

7. A method of manufacturing a semiconductor device, comprising the steps of:
forming a gate insulating film on a semiconductor substrate; and
forming a gate electrode on the gate insulating film;
wherein the gate insulating film is formed by thermally oxidizing a surface region of the semiconductor substrate, followed by oxynitriding the thermal oxide film within a furnace by using a NO gas-based atmosphere containing 1/10 or less of oxygen.

8. A method of manufacturing a semiconductor device according to claim 7, wherein said oxynitriding treatment is carried out at 700 to 1100° C.

9. A method of manufacturing a semiconductor device, comprising the steps of:
forming a gate insulating film on a semiconductor substrate; and
forming a gate electrode on the gate insulating film;
wherein the gate insulating film is formed by an oxynitriding treatment within a furnace by using a NO gas-based atmosphere containing 1/10 or less of oxygen.

10. A method of manufacturing a semiconductor device according to claim 9, wherein said oxynitriding treatment is carried out at 700 to 1100° C.
